(19) United States
(12) Patent Application Publication
(10) Pub. No.: US 2026/0279478 A1
(43) Pub. Date: Sep. 17, 2026

(54) ADJUSTMENT TO MULTI-PHASE CLOCK TO REDUCE SKEW VARIATION CAUSED BY POWER RAIL BOUNCE AT ONSET OF BURST OF DATA

(71) Applicant: Micron Technology, Inc., Boise, ID (US)

(72) Inventors: Ki-Jun Nam, Richardson, TX (US); Ping Na Li, Plano, TX (US)

(21) Appl. No.: 19/535,927

(22) Filed: Feb. 10, 2026

Related U.S. Application Data
(60) Provisional application No. 63/772,318, filed on Mar. 14, 2025.

(51) Int. Cl. G11C 29/12; G11C 11/4093; G11C 29/02; H03L 7/081; H04L 7/033; H04L 25/14

(52) U.S. Cl. CPC G11C 29/12015; G11C 11/4093; G11C 29/028; H03L 7/0814; H04L 7/033; H04L 25/14

(57) ABSTRACT

Methods, systems, and devices for adjustment to multi-phase clock to reduce skew variation caused by power rail bounce at an onset of a burst of data are described. In accordance with examples as described herein, a memory system may be configured to reduce skew variations between a multi-phase clock and a differential clock caused by power rail bounce during a burst write operation. The memory system may include circuitry including a block of detection/pulse generation circuitry configured to detect a leading phase of the multi-phase clock at an onset of a burst write operation and generate pulse signaling that is indicative of the leading phase. The circuitry may further a block of adder circuitry that is configured to determine, based at least in part on using the pulse signaling, one or more timing adjustments that compensate for the skew variations.

### CROSS REFERENCE

The present Application for Patent claims priority to U.S. Patent Application No. 63/772,318 by Nam et al., entitled “ADJUSTMENT TO MULTI-PHASE CLOCK TO REDUCE SKEW VARIATION CAUSED BY POWER RAIL BOUNCE AT ONSET OF BURST OF DATA ,” filed Mar. 14, 2025, which is assigned to the assignee hereof, and which is expressly incorporated by reference in its entirety herein.

### TECHNICAL FIELD

The following relates to one or more systems for memory, including adjustment to a multi-phase clock to reduce skew variation caused by power rail bounce at an onset of a burst of data.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports adjustment to a multi-phase clock to reduce skew variation caused by power rail bounce at an onset of a burst of data in accordance with examples as disclosed herein.

FIG. 2 shows an example of an implementation that supports adjustment to a multi-phase clock to reduce skew variation caused by power rail bounce at an onset of a burst of data in accordance with examples as disclosed herein.

FIG. 3 shows an example of circuitry that supports adjustment to a multi-phase clock to reduce skew variation caused by power rail bounce at an onset of a burst of data in accordance with examples as disclosed herein.

FIG. 4 shows example timing diagrams of digital signaling that supports adjustment to a multi-phase clock to reduce skew variation caused by power rail bounce at an onset of a burst of data in accordance with examples as disclosed herein.

FIG. 5 shows a block diagram of an apparatus that supports adjustment to a multi-phase clock to reduce skew variation caused by power rail bounce at an onset of burst of data in accordance with examples as disclosed herein.

FIG. 6 shows a flowchart illustrating a method or methods that support adjustment to a multi-phase clock to reduce skew variation caused by power rail bounce at an onset of a burst of data in accordance with examples as disclosed herein.

### DETAILED DESCRIPTION

An apparatus may include a host system that is in electronic communication with a memory system that includes double data rate (DDR) dynamic random access memory (DRAM). As part of an operation during which the host system provides information to the memory system (e.g., a burst write operation), the data may be communicated over a link using a differential clock that is relatively fast. The memory system may divide the differential clock to a multi-phase clock (e.g., a multi-phase data strobe signal, or DQS) to capture and store (e.g., “latch”) the information at a specific time during that the information is valid. Such a specific time may correspond to a time during which a phase of the DQS transitions (e.g., a rising edge of a phase of the multi-phase clock). Circuitry including phase dividing circuitry may be used to generate the multi-phase clock from the differential clock. One or more electrical paths along the circuitry may introduce a skew (e.g., a timing lag) between the differential clock and phases of the multi-phase clock.

In some cases (e.g., at an onset of a burst of data during a write operation after an idle period), a power rail bounce may introduce a variation in the skew across phases of the multi-phase clock and the circuitry may not fully compensate for such a variation. As such, and particularly for phases of the multi-phase clock that are used to latch first sets of bits of the burst of data, alignments between rising edges of the phases and centers of data eyes used to latch the first sets of bits may be compromised, reducing a functional margin available to the apparatus during burst of data. Reducing the functional margin may limit a speed of the write operation and/or introduce an error during latching of the first bits, among other examples.

In accordance with examples as described herein, a memory system may be configured to reduce skew variation among phases of multi-phase clock caused by power rail bounce during a burst of data that may be part of a write operation. The memory system may include circuitry including a block of circuitry configured to detect a leading phase of the multi-phase clock at an onset of a burst write operation and generate pulse signaling that is indicative of the leading phase. The circuitry may further include a block of circuitry that is configured to determine, based at least in part on using the pulse signaling, one or more timing adjustments that compensate for the skew variation. The circuitry may further include a block, of circuitry that implements the one or more timing adjustments to compensate for the skew variation, thereby improving a functional margin available to the memory system to latch data during the onset of the burst of data. By improving the functional margin, a speed of the write operation may be increased. Additionally, or alternatively, a likelihood of latching errors during the write operation may be decreased.

In addition to applicability in memory systems as described herein, techniques for adjusting the multi-phase clock to reduce skew variation caused by power rail bounce at an onset of a burst of data may be generally implemented to support increased connectivity of electronic systems. As the use of systems relying on interconnected electronic devices increases, the connectivity of these electronic devices becomes an increasingly relevant factor for the operations of the system. For example, delays associated with signals communicated between devices may become increasingly relevant as critical systems come to rely more on connectivity, as a system uses larger quantities of interconnected devices, or if the quantity and the complexity of signals communicated between devices increases. Implementing the techniques described herein may support techniques for increased connectivity in electronic systems by improving data transfer between devices, reducing a likelihood of data latching errors during an onset of a burst write operation, and/or enabling increased communications between devices, among other benefits.

Features of the disclosure are illustrated and described in the context of systems and architectures. Features of the disclosure are further illustrated and described in the context of an implementation of the techniques during an onset of a burst write operation, circuitry supporting the implementation of the techniques, digital signaling used by the circuitry, and flowcharts.

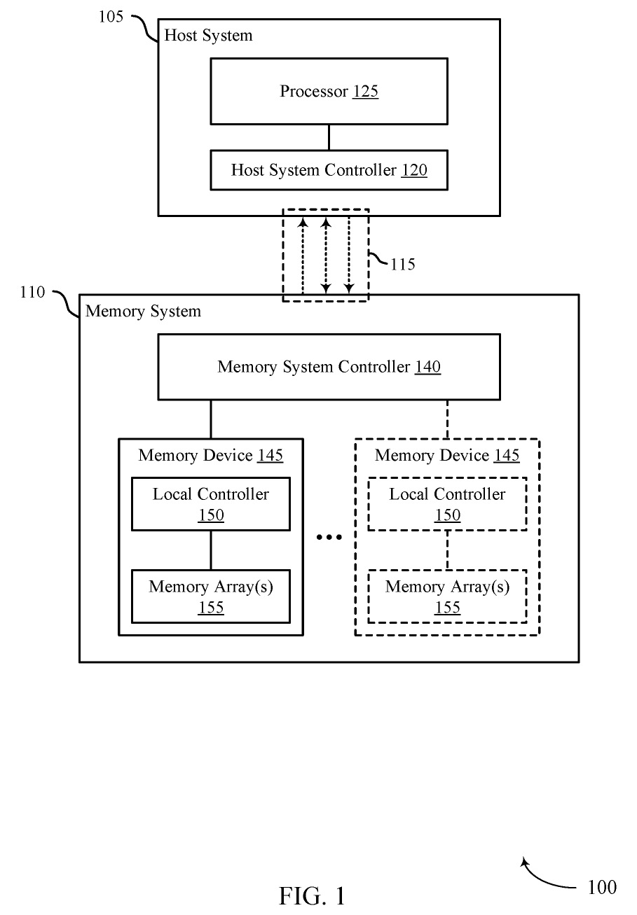

FIG. 1 shows an example of a system 100 that supports adjustment to multi-phase clock to reduce skew variation caused by power rail bounce at an onset of a burst of data in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

A host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). A processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. A processor 125 may be an example of a central processing unit (CPU), a graphics processing unit (GPU), a general-purpose GPU (GPGPU), or an SoC or a component thereof, among other examples.

A host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating a memory system 110, such as write commands, read commands, configuration signaling or other operational signaling. In some examples, a host system controller 120, or associated functions described herein, may be implemented by or be part of a processor 125. For example, a host system controller 120 may be hardware, instructions (e.g., software, firmware), or a combination thereof implemented by a processor 125 or other component of a host system 105. In various examples, a host system 105 or a host system controller 120 may be referred to as a host.

A memory system 110 provides physical memory locations (e.g., addresses) that may be used or referenced by the system 100. A memory system 110 may include a memory system controller 140 and one or more memory devices 145 (e.g., memory packages, memory dies, portions of a memory die) operable to store data. A memory system 110 may be configurable for operations with different types of host systems 105, and may respond to commands from the host system 105 (e.g., from a host system controller 120). For example, a memory system 110 (e.g., a memory system controller 140) may receive a write command indicating that the memory system 110 is to store data received from a host system 105, or receive a read command indicating that the memory system 110 is to provide data stored in a memory device 145 to a host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of a memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with a host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

A clock signal channel may be operable to communicate one or more clock signals between the host system 105 and the memory system 110. Clock signals may oscillate between a high state and a low state, and may support coordination (e.g., in time) between operations of the host system 105 and the memory system 110. In some examples, a clock signal may provide a timing reference for operations of the memory system 110. A clock signal may be referred to as a control clock signal, a command clock signal, or a system clock signal. A system clock signal may be generated by a system clock, which may include one or more hardware components (e.g., oscillators, crystals, logic gates, transistors).

A data channel (e.g., a DQ channel) may be operable to communicate (e.g., bidirectionally) information (e.g., data, control information) between the host system 105 and the memory system 110. For example, a data channel may communicate information from the host system 105 to be written to the memory system 110, or information read from the memory system 110 to the host system 105. In some examples, channels 115 may include one or more error detection code (EDC) channels. An EDC channel may be operable to communicate error detection signals, such as checksums or parity bits, which may accompany information conveyed over a data channel.

Signaling may be communicated over the channels 115 using single data rate (SDR) signaling or double data rate (DDR) signaling, among other rates (e.g., relative to a clock signal). In SDR signaling, one modulation symbol (e.g., signal level) of a signal may be registered for each clock cycle (e.g., on a rising edge or a falling edge of a clock signal). In DDR signaling, two modulation symbols of a signal may be registered for each clock cycle (e.g., on both a rising edge and a falling edge of a clock signal).

Signals communicated over the channels 115 may be modulated using various modulation schemes or combinations thereof. A symbol of a binary-symbol (e.g., binary-level) modulation scheme may be operable to represent one bit of data (e.g., a symbol may represent a logic 1 or a logic 0), and may be an example of an M-ary modulation scheme where M is equal to two. Examples of binary-symbol modulation schemes include non-return-to-zero (NRZ), unipolar encoding, bipolar encoding, Manchester encoding, pulse amplitude modulation (PAM) having two symbols (e.g., PAM2), and others. A symbol of a multi-symbol modulation scheme may be operable to represent more than one bit of data (e.g., a symbol may represent a logic 00, a logic 01, a logic 10, or a logic 11), and may be an example of an M-ary modulation scheme where M is greater than or equal to three. For example, a multi-symbol signal may be modulated using a modulation scheme that includes at least three levels to encode more than one bit of information. Multi-symbol modulation schemes and symbols may be referred to as non-binary, multi-bit, or higher-order modulation schemes and symbols. Examples of multi-symbol modulation schemes include PAM3, PAM4, PAM8, and so on, quadrature amplitude modulation (QAM), quadrature phase shift.

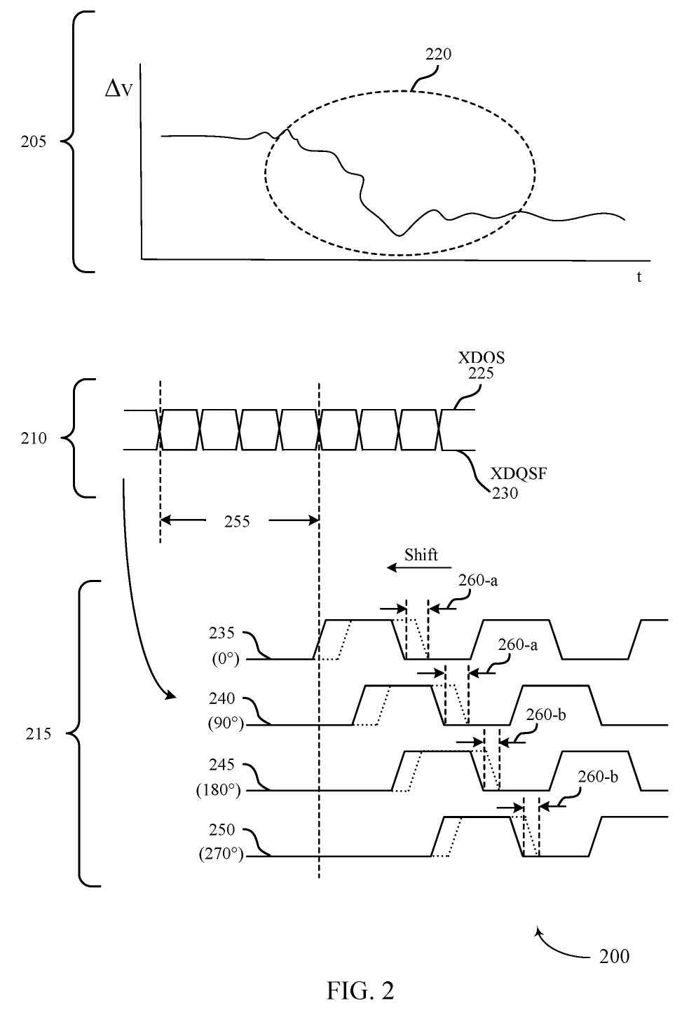

In some examples, and as described in greater detail in connection with FIGS. 2 through 5, a differential clock and a multi-phase clock used by the memory system 110 to latch data may be subject to a power rail bounce that causes skew variation between the differential clock and the multi-phase clock during an onset of a burst of data (e.g., at the beginning of a burst write operation). To compensate for the skew variation, the memory system 110 may include circuitry configured to detect a leading phase of the multi-phase clock at the onset and generate pulse signaling that is indicative of the leading phase. The circuitry may further be configured to determine, based at least in part on using the pulse signaling, one or more timing adjustments that compensate for the skew variation.

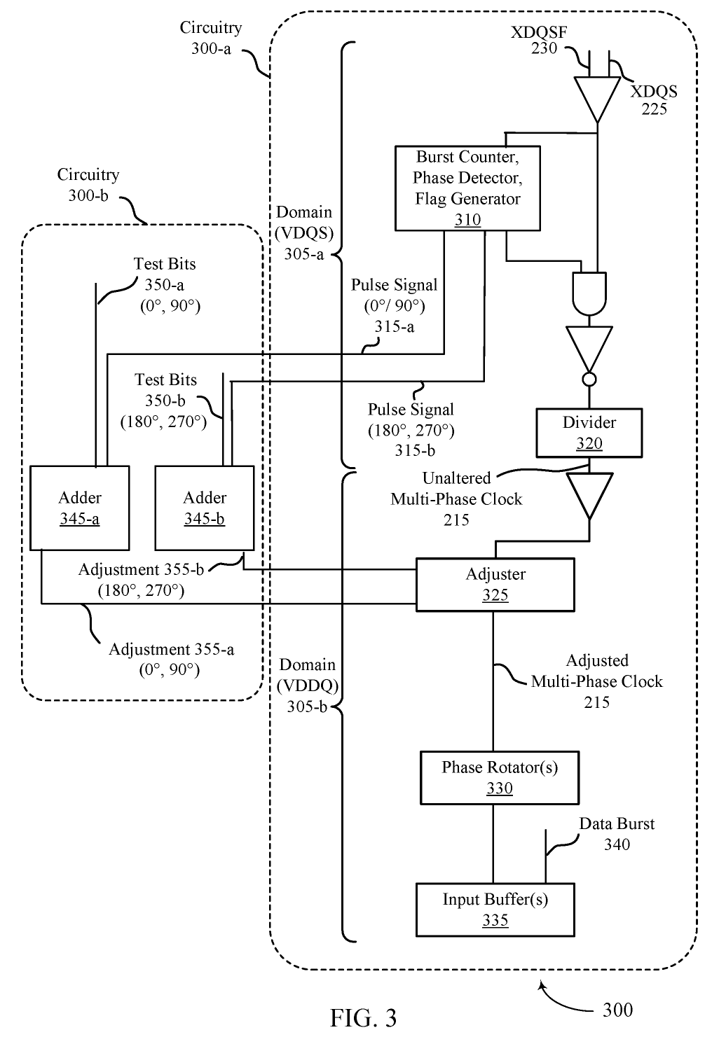

FIG. 2 shows an example of an implementation 200 that supports adjustment to a multi-phase clock to reduce skew variation caused by power rail bounce at an onset of a burst of data in accordance with examples as disclosed herein. Implementation 200, as shown in FIG. 2, describes aspects of a voltage behavior 205 of a power rail, a differential clock 210, and a multi-phase clock 215 that may be included in a memory system (e.g., the memory system 110 as described in connection with FIG. 1) that includes DDR DRAM memory. In some examples, and as described in greater detail in connection with FIGS. 3 through 6, one or more aspects of the voltage behavior 205, the differential clock 210, and/or the multi-phase clock 215 may be implemented using circuitry included in the memory system (e.g., included in the memory system controller 140 and/or the memory device 145 as described in connection with FIG. 1). to a data strobe (e.g., VDQS) used by the memory system and a ground reference voltage.

In some examples, the voltage behavior 205 may be quantified as a difference (ΔV) between a power rail that generating and/or supplying a voltage e (e.g., VSSQ) to a system (e.g., the memory system 100). Additionally, or alternatively, and in some examples, the voltage behavior 205 may be a difference between a power rail that that generates and/or supplies a voltage to inputs/outputs (e.g., VDDQ) used by the memory system and the ground reference voltage.

The voltage behavior 205 may be characterized as a function of time (t) during the onset of the burst of data. In some examples, the onset of the burst of data may correspond to an onset of a write operation performed by the memory system. As shown in FIG. 2, and during the onset of the burst of data, the voltage behavior 205 may include a power rail bounce 220 that includes relatively high variation, droop, and/or instability due to circuitry of the memory system being activated at the onset of the write operation. For example, if the link that communicates data is idle, then the beginning of a data burst may cause a draw of power that causes the bounce. In some circumstances, if there is a string of continuous communication, the power rail may stabilize throughout the continuous communications and may not experience the bouncing at the beginning of every burst of data.

As shown in FIG. 2 the differential clock 210 may include an extended data strobe signal (XDQS) 225 and/or an extended data strobe forwarding signal (XDQSF) 230. In some examples, XDQS 225 and/or XDQSF 230 may provide timing references to establish data eyes (e.g., valid timing windows) used by the memory system to latch data during a write operation.

Additionally, or alternatively and as described in greater detail in connection with FIG. 3, circuitry of the memory system may use the differential clock 210 to generate the multi-phase clock 215. The multi-phase clock 215 may include phase 235 that is a zero degree (0°) reference phase, phase 240 that is ninety degree (90°) phase, phase 245 that is a hundred-and-eighty degree (180°) phase, and phase 250 that is a two hundred-and-seventy degree (270°) phase. In some examples, a rising edge of a phase may be used by the memory system to latch data during a write operation (e.g., a rising edge of a phase that is centered with a data eye may enable a valid latching of the data).

In some examples, a circuitry path between the differential clock (e.g., XDQS 225 and XDQSF 230) and an input buffer of the memory system may introduce a skew 255 (e.g., a timing lag and/or a delay) between unit intervals of differential clock 210 and the multi-phase clock 215. The skew 255 may be applicable to rising edges of the unit intervals, centers of the unit intervals and/or falling edges of the unit intervals. In some examples, and during the onset of the burst of data, the power rail bounce 220 may cause variations and/or increases in the skew 255 for initial unit intervals of phases of the multi-phase clock 215.

As described in greater detail in connection with FIGS. 3 through 6, circuitry of the memory system may determine that a data channel over which the burst of data is conveyed is in an idle state prior to the onset of the burst of data. In such a situation, it may be more likely that the power rail bounce 220 may occur. Based at least in part on the determination, the circuitry may generate one or more timing adjustments that compensate for increases in the skew 255 due to the power rail bounce 220. Additionally, or alternatively, and in some examples the circuitry may determine a leading phase of the multi-phase clock 215, where the leading phase is used to latch a first set of bits of the burst of data. In some examples, the circuitry may determine that the 0° reference phase 235 is the leading phase. In other examples, the circuitry may determine that the 180° phase 245 is the leading phase.

The circuitry may then use the timing adjustments to shift unit intervals of two or more phases of the multi-phase clock 215 that are used to latch data at the onset of the burst of data. Shifting the two or more unit intervals may improve centering of edges of the two or more unit intervals with data eyes used to latch the data.

As an example, and as shown in FIG. 2, the circuitry may determine that the phase 235 (e.g., a zero-degree reference phase) is the leading phase, generate a timing adjustment 260-a, and apply the timing adjustment 260-a to a unit interval of the phase 235. Applying the timing adjustment 260-a to the unit interval (of the phase 235) may improve centering of a leading edge of the unit interval with a data eye during latching of a first set of bits of the burst of data. The circuitry may further apply the timing adjustment 260-a to a unit interval of phase 240. Applying the timing adjustment 260-a to the unit interval (of the phase 235) may improve centering of a leading edge of the unit interval with a data eye during latching of a second set of bits of the burst of data.

In some examples, and as further shown in FIG. 2, the circuitry may generate a timing adjustment 260-b and apply the timing adjustment 260-b to a unit interval of the phase 245. In some examples, a magnitude of the timing adjustment 260-b may be less than a magnitude of the timing adjustment 260-a. Applying the timing adjustment 260-b to the unit interval (of the phase 245) may improve a centering of a leading edge of the unit interval with a data eye during latching of a third set of bits of the burst of data.

In some examples, and as further shown in FIG. 2, the circuitry may apply the timing adjustment 260-b to a unit interval of the phase 250. Applying the timing adjustment 260-b to the unit interval (of the phase 250) may improve a centering of a leading edge of the unit interval with a data eye during latching of a fourth set of bits of the burst of data.

In this way, the circuitry may reduce a variation of the skew 255 across the phases during a burst of data. Reducing the variation of the skew may improve a functional margin available to the memory system to latch data during the onset of the burst of data. By improving the functional margin, a speed of a burst write operation generating the burst of data may be increased. Additionally, or alternatively, a likelihood of latching errors during the burst write operation may be decreased.

FIG. 3 shows an example of circuitry 300 that supports adjustment to a multi-phase clock to reduce skew variation caused by power rail bounce at an onset of a burst of data in accordance with examples as disclosed herein. The circuitry includes circuitry 300-a and circuitry 300-b, which may perform operations that include generating the multi-phase clock 215, applying timing adjustments to unit intervals of the multi-phase clock 215 to adjust for a variation in skew at the onset of the burst of data, and latching initial sets of bits of the burst of data using the adjusted unit intervals. In some examples, operations performed by the circuitry 300 may be performed a memory system (e.g., the memory system 110 as described in connection with FIG. 1) while the memory system is in a write training mode.

As described in greater detail below, the circuitry 300-a and/or the circuitry 300-b may include a combination of one or more logic blocks. Each logic block may include a combination of circuit elements (logic gates, flip-flops, counters, shift registers, clock dividers, multiplexers, demultiplexers, arithmetic logic units, voltage regulators, digital signal processing units, and/or other suitable circuitry elements, among other examples) configured to perform a specific operation described herein.

As shown in FIG. 3, the circuitry 300-a may span power domain 305-a and power domain 305-b. In some examples, the power domain 305-a (e.g., a VDQS power domain) may be a power domain associated with clock signals for data strobes used by the memory system. Additionally, or alternatively, the power domain 305-b (e.g., a VDDQ power domain) may be a power domain associated with inputs/outputs of the memory system.

As shown in FIG. 3, the circuitry 300-a may include a logic block 310. In some examples, the logic block 310 may include a combination of circuit elements configured to receive one or more differential clock signals (e.g., XDQS 225 and/or XDQSF 230), where the one or more differential clock signals may be conditioned by an operational amplifier and/or another circuit element.

Additionally, or alternatively, and in some examples, the logic block 310 may include a combination of circuit elements configured to detect a burst condition and digitally count (and/or control) a burst of data conveyed through a data channel. As part of detecting the burst condition, the combination of circuit elements detect an idle state of the data channel prior to an onset of the burst of data.

Additionally, or alternatively, and in some examples, the logic block 310 may include a combination of circuit elements configured to detect a leading phase of the multi-phase clock 215 at the onset of the burst of data. In some cases, the onset of the burst of data can happen on any edge of the differential clock (or possibly on any rising edge of the one of the clocks of the differential clock). While one phase of the multi-phase clock 215 is labeled as the leading phase (e.g., 0 degrees out of phase), any of the phases could be the leading phase of a particular burst given the timing of the burst relative to the multi-phase clock. Depending on when the burst begins, it may change which phase of the multi-phase clock 215 is the leading phase for that burst. Detecting the leading phase may include using a return mapping technique or another suitable detecting technique, among other examples.

Additionally, or alternatively, and in some examples, the logic block 310 may include a combination of circuit elements configured to generate pulse signaling that is indicative of the leading phase. In some examples, the logic block 310 may generate pulse signal 315-a that indicates a 0° reference phase (e.g., the phase 235) of the multi-phase clock 215 is the leading phase. Alternatively, and in some examples, the logic block 310 may generate pulse signal 315-b that indicates a 180°phase (e.g., the phase 245) of the multi-phase clock 215 is the leading phase.

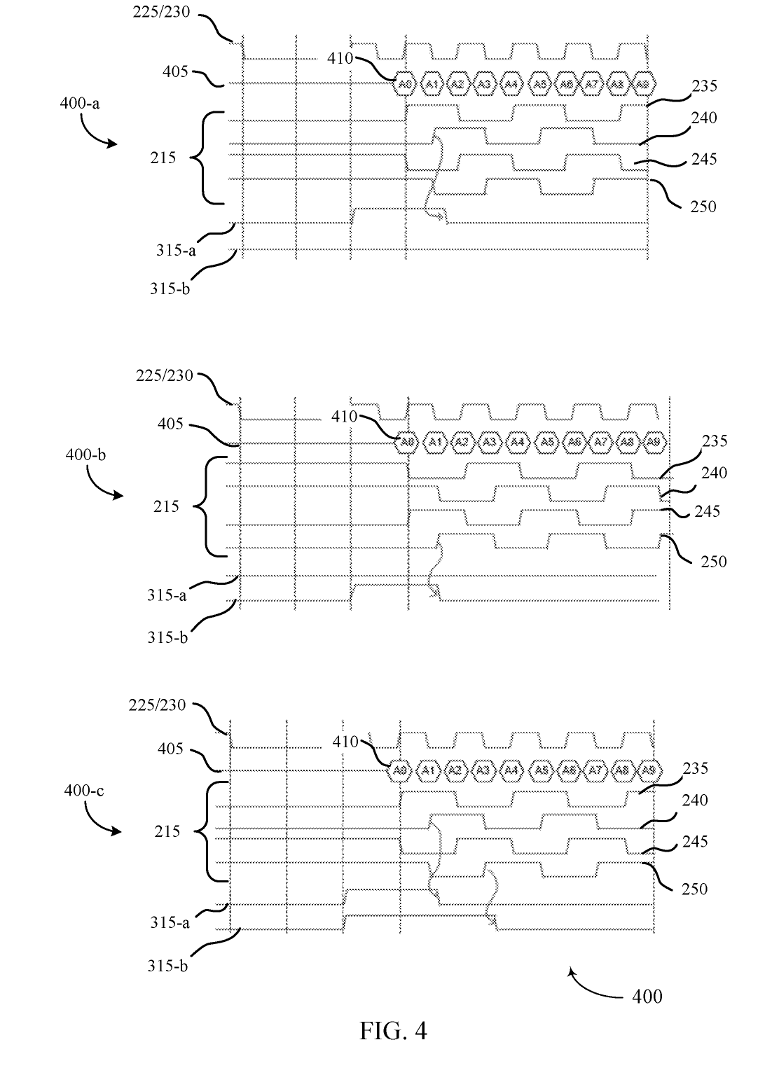

In some examples and described in greater detail in connection with FIG. 4, the pulse signal 315-a and/or the pulse signal 315-b may include different combinations of flag outputs that may be toggled, enabled, and or cleared. Based on a particular sequence and/or combination of flag outputs included in the pulse signal 315- a and/or the pulse signal 315-b, the circuitry 300 may adjust timing of phases used to latch a first two sets of bits at the onset of the burst of data, a first three sets of bits at the onset of the burst of data, and/or a first four sets of bits at the onset of the burst of data.

As further shown in FIG. 3, the circuitry 310-a may include a logic block 320. In some examples, the logic block 320 may include a combination of circuit elements configured receive portions of the differential clock signal and/or signaling from the logic block 310 that may be conditioned by a logic gate and/or an operational amplifier. Additionally, or alternatively, and in some examples, the circuit elements of the logic block 320 may be further configured to divide the signaling to generate the multi-phase clock 215. The multi-phase clock 215, after being generated by the circuit elements of the logic block 320, may be in an unaltered state. In the unaltered state, the multi-phase clock may have a duty cycle that is imbalanced and further have a substantial variation in a skew across one or more phases (e.g., across the 235, the phase 240, the phase 245, and/or the phase 245).

As further shown in FIG. 3, the circuitry 310-a may include a logic block 325. In some examples, the logic block 325 may include a combination of circuit elements configured receive portions of the multi-phase clock 215, in the unaltered state, which have been conditioned by an amplifier and/or another circuit element. Additionally, or alternatively, and in some examples, the circuit elements of the logic block 325 may be further configured to adjust one or more timing parameters related to the multi-phase clock 215. For example, the circuit elements of the logic block 325 may be configured to adjust a duty cycle of the multi-phase clock. Additionally, or alternatively, and as described in greater detail below, the circuit elements of the logic block 325 may be configured to receive and apply timing adjustments to phases of the multi-phase clock 215 to reduce a variation in a skew across one or more phases. After adjusting the one or more timing parameters, the logic block 325 may output the multi-phase clock 215 in an adjusted state.

As further shown in FIG. 3, the circuitry 310-a may include a logic block 330. In some examples, the logic block 330 may include circuit elements configured to rotate and/or shift phases of the multi-phase clock 215 at a finer granularity. The circuit elements rotate and/or shift the phases at the finer granularity to compensate for process, voltage, and/or temperature variations to further ensure timing margins (e.g., alignment between edges of the multi-phase clock 215 and data eyes used to latch sets of bits) are sufficient to write and/or latch a burst of data with a reduced likelihood of error

As further shown in FIG. 3, the circuitry 310-a may include a logic block 335. In some examples, the logic block 330 may include circuit elements configured to receive the multi-phase clock 215 (in a fully adjusted state) from the logic block 330 and a burst of data 340. The circuit elements of the logic block 330 may further be configured to use phases of the multi-phase clock 215 to latch sets of bits of the burst of data 340, where the phases include timing adjustments that reduce a variation in skew across the phases.

As shown in FIG. 3, the circuitry 320-b may include logic block 345-a. In some examples, the logic block 345-a may include circuit elements configured to receive the pulse signal 315-a from the logic block 310 and test bits 350-a from a register. The test bits 350-a may correspond to a pair of phases of the multi-phase clock 215, including a 0° reference phase (e.g., the phase 235) and a 90° phase (e.g., the phase 240). Additionally, or alternatively, the test bits 350-a may be indicative of a value of a timing adjustment to be added to one or more of the pair of phases to compensate for a skew at the onset of a burst of data. The circuit elements of the logic block 345-a may further be configured provide a timing adjustment 355-a to be used by the logic block 325.

As shown in FIG. 3, the circuitry 320-b may include logic block 345-b. In some examples, the logic block 345-a may include circuit elements configured to receive the pulse signal 315-b from the logic block 310 and test bits 350-b from the register. The test bits 350-b may correspond to a pair of phases of the multi-phase clock 215, including a 180° phase (e.g., the phase 245) and a 270° phase (e.g., the phase 245). Additionally, or alternatively, the test bits 350-b may be indicative of a value of a timing adjustment to be added to one or more of the pair of phases to compensate for a skew at the onset of the burst of data. The circuit elements of the logic block 345-b may further be configured provide a timing adjustment 355-b to be used by the logic block 325.

FIG. 4 shows example timing diagrams 400 of digital signaling that supports adjustment to multi-phase clock to reduce skew variation caused by power rail bounce at an onset of a burst of data in accordance with examples as disclosed herein. As shown in FIG. 4, the timing diagrams 400 (e.g., the timing diagram 400-a, the timing diagram 400-b, and the timing diagram 400-c) each include a data strobe (e.g., XDQS 225 or XDQSF 230) and the multi-phase clock 215 including the phase 235 (e.g., a 0° reference phase), the phase 240 (e.g., a 90°phase), the phase 245 (e.g., a 180°phase), and the phase 245 (e.g., a 270°phase). The timing diagrams 400 further each include an input/output (I/O) signal 405 (e.g., a DQ signal) and unit intervals 410 (e.g., timing windows during which latching of data corresponding to a state of the I/O signal 405 is valid).

The timing diagrams 400 further each include digital signaling comprising the pulse signal 315-a and the pulse signal 315-b. In some examples, a combination of one or more logic blocks included in a memory system (e.g., the logic block 345-a, the logic block 345-b, and/or the logic block 325 as described in connection with FIG. 3) may use the pulse signal 315-a and/or the pulse signal 315-b (e.g., flag outputs of the logic block 310 as described in connection with FIG. 3) as part of reducing skew variation caused by power rail bounce at an onset of a burst of data.

Timing diagram 400-a shows an example of digital signaling that may be used to latch a first two sets of bits during a burst of data. In timing diagram 400-a, a logic block (e.g., the logic block 310 as described in connection with FIG. 3) may determine that the phase 235 (e.g., the 0° reference phase of the multi-phase clock 215) is the leading phase. As part of latching the first two sets of bits during the burst of data, the logic block may generate digital signaling that includes toggling the pulse signal 315-a from an enabled state (e.g., a high state) to a cleared state (e.g., a low state). Furthermore, the logic block may generate signaling that includes clearing the pulse signal 315-b (e.g., maintaining the signal in a low state). In some examples, and as shown in timing diagram 400-a, toggling the pulse signal 315-a may include toggling the pulse signal 315-a at a same approximate time as a rising edge of the phase 240.

In accordance with timing diagram 400-a and based at least in part on the pulse signal 315-a and the pulse signal 315-b, one or more additional logic blocks (e.g., the logic block 345-a and/or the logic block 325) may implement timing adjustments to unit intervals of the phase 235 and the phase 240. The timing adjustments may improve a centering of rising edges of the phase 235 and the phase 240 with unit intervals 410 (e.g., A0 and A1) during latching of the first two sets of bits.

Timing diagram 400-b shows another example of digital signaling that may be used to latch a first two sets of bits during a burst of data. In contrast to the timing diagram 400-a, the timing diagram 400-b represents an example in which a logic block (e.g., the logic block 310 as described in connection with FIG. 3) may determine that the phase 245 (e.g., the 180° phase of the multi-phase clock 215) is the leading phase. As part of latching the first two sets of bits during the burst of data, the logic block may generate digital signaling that includes clearing the pulse signal 315-a and toggling the pulse signal 315-b from an enabled state to a cleared state. In some examples, and as shown in timing diagram 400-b, toggling the pulse signal 315-b may include toggling the pulse signal 315-b at a same approximate time as a rising edge of the phase 250.

In accordance with timing diagram 400-b and based at least in part on the pulse signal 315-a and the pulse signal 315-b, a combination of one or more additional logic blocks (e.g., the logic block 345-a, the logic block 345-b, and/or the logic block 325) may implement timing adjustments to unit intervals of the phase 245 and the phase 250. The timing adjustments may improve a centering of rising edges of the phase 245 and the phase 250 with unit intervals 410 (e.g., A0 and A1) during latching of the first two sets of bits.

Timing diagram 400-c shows another example of digital signaling that may be used to latch a first four sets of bits during a burst of data. The timing diagram 400-c represents an example in which a logic block (e.g., the logic block 310 as described in connection with FIG. 3) may determine that the phase 235 (e.g., the 0° reference phase of the multi-phase clock 215) is the leading phase. As part of latching the first four sets of bits during the burst of data, the logic block may generate digital signaling that includes toggling the pulse signal 315-a and toggling the pulse signal 315-b. In some examples, and as shown in timing diagram 400-b, toggling the pulse signal 315-a may include toggling the pulse signal 315-a from an enabled state to a cleared state at a same approximate time as a rising edge of the phase 240. Additionally, or alternatively, and as shown in timing diagram 400-c, toggling the pulse signal 315-b may include toggling the pulse signal 315-b from an enabled state to a cleared state at a same approximate time as a rising edge of the phase 250.

In accordance with timing diagram 400-c and based at least in part on the pulse signal 315-a and the pulse signal 315-b, one or more additional logic blocks (e.g., the logic block 345-a, the logic block 345-b, and/or the logic block 325) may implement timing adjustments to unit intervals of the phase 235, the phase 240, the phase 245, and/or the phase 250. The timing adjustments may improve a centering of rising edges of phase 235, the phase 240, the phase 245, and/or the phase 250 with unit intervals410 (e.g., A0, A1, A2, and/or A3) during latching of the first four sets of bits.

Other digital signaling may be implemented to generate timing adjustments that are used to compensate for skew during latching of a first three sets of bits. For example, and based on a configuration of the logic block 345-a, the logic block 345-b, and/or the logic block 325, the digital signaling used to compensate for skew during latching of the first three sets of bits may include toggling both the pulse signal 315-a and the pulse signal 315-b.

As described in connection with FIGS. 1 through 4, and in some examples, an apparatus (e.g., the memory system 100) includes first circuitry (e.g., the circuitry 300-a). The first circuitry may be configured to generate a multi-phase clock signal (e.g., the unadjusted multi-phase clock 215) based at least in part on a differential clock signal (e.g., the differential clock including XDQS 225 and/or XDQSF 230). The first circuitry may further be configured to detect a leading phase (e.g., the phase 235 or the phase 245) at the onset of the burst of data associated with a write operation and generate pulse signaling (e.g., the pulse signal 315-a and/or the pulse signal 315-b) that is indicative of the leading phase. The apparatus may further include second circuitry (e.g., the circuitry 300-b) that is configured to receive the pulse signaling from the first circuitry and determine, using the pulse signaling, a timing adjustment (e.g., the timing adjustment 260) that compensates for an increase in a skew (e.g., the skew 255) between the leading phase and the differential clock signal caused by a power rail bounce (e.g., the power rail bounce 220) at the onset of the burst of data. The second circuitry may further be configured to provide the timing adjustment to the first circuitry to shift a unit interval of the leading phase to improve a centering of an edge of the unit interval with a unit interval (e.g., the unit interval 410) at the onset of the burst of data.

By improving the centering and reducing the skew, the apparatus may improve a functional margin available to the apparatus to latch data during the onset of the burst of data. By improving the functional margin, a speed of a burst write operation generating the burst of data may be increased. Additionally, or alternatively, a likelihood of latching errors during the burst write operation may be decreased.

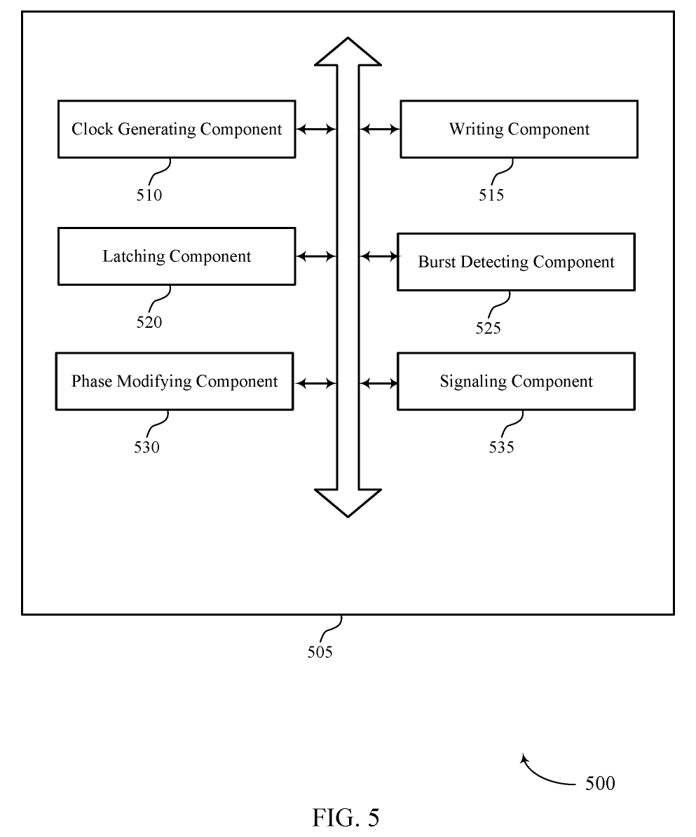

FIG. 5 shows a block diagram 500 of an apparatus 505 that supports adjustment to multi-phase clock to reduce skew variation caused by power rail bounce at an onset of a burst of data in accordance with examples as disclosed herein. The apparatus 505 may be an example of aspects of a memory system (e.g., the memory system 100) as described with reference to FIGS. 1 through 4. The apparatus 505, or various components thereof, may be an example of means for performing various aspects of adjustment to multi-phase clock to reduce skew variation caused by power rail bounce at an onset of a burst of data as described herein. For example, the apparatus 505 may implement circuitry inclusive of a clock generating component 510, a writing component 515, a latching component 520, a burst detecting component 525, a phase modifying component 530, a signaling component 535, or any combination thereof. Each of these components, or components of subcomponents thereof (e.g., one or more processors, one or more memories), may communicate, directly or indirectly, with one another (e.g., via one or more buses).

The clock generating component 510 may be configured as or otherwise support a means for generating a multi-phase clock signal based at least in part on a differential clock signal. The writing component 515 may be configured as or otherwise support a means for generating a burst of data associated with a write operation. The latching component 520 may be configured as or otherwise support a means for latching a first set of bits of the burst of data during a first unit interval associated with a first phase of the multi-phase clock signal, where the first unit interval is offset by a timing adjustment that compensates for a skew between the differential clock signal and the first phase caused by a power rail bounce during an onset of the burst of data. In some examples, the latching component 520 may be configured as or otherwise support a means for latching a second set of bits during the burst of data during a second unit interval associated with a second phase of the multi-phase clock signal, where the second unit interval is offset by the timing adjustment.

In some examples, the latching component 520 may be configured as or otherwise support a means for latching a third set of bits of the burst of data using a third unit interval associated with a third phase of the multi-phase clock signal. In some examples, latching component may be configured as or otherwise support a means for where the third unit interval is offset by a second timing adjustment that compensates for a second skew between the differential clock signal and the third phase caused by the power rail bounce during the onset of the burst of data.

In some examples, the latching component 520 may be configured as or otherwise support a means for latching a fourth set of bits of the burst of data using a fourth unit interval associated with a fourth phase of the multi-phase clock signal, where the fourth unit interval is offset by the second timing adjustment.

In some examples, a data channel over which the burst of data is conveyed is in an idle state before the burst of data begins.

In some examples, the burst detecting component 525 may be configured as or otherwise support a means for determining whether a data channel over which the burst of data is conveyed is an idle state before the burst of the data begins. In some examples, the phase modifying component 530 may be configured as or otherwise support a means for modifying the first phase of the multi-phase clock signal with the timing adjustment based at least in part on determining that the data channel was idle, where latching the first set of bits is based at least in part on modifying the first phase.

In some examples, the phase modifying component 530 may be configured as or otherwise support a means for retrieving a first value of the timing adjustment from a register. In some examples, the phase modifying component 530 may be configured as or otherwise support a means for modifying the first value of the timing adjustment to a second value, where latching the first set of bits is based at least in part on the second value of the timing adjustment.

In some examples, to support modifying the first value to the second value, the phase modifying component 530 may be configured as or otherwise support a means for adding a third value to the first value to generate the second value.

In some examples, the signaling component 535 may be configured as or otherwise support a means for generating a signal indicating that the data channel was in the idle state based at least in part on the determining, where modifying the first phase is based at least in part on generating the signal.

In some examples, the described functionality of the apparatus 505, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the apparatus 505, or various components thereof, may be implemented at least in part by instructions (e.g., stored in memory, non-transitory computer-readable medium) executable by such at least one processor.

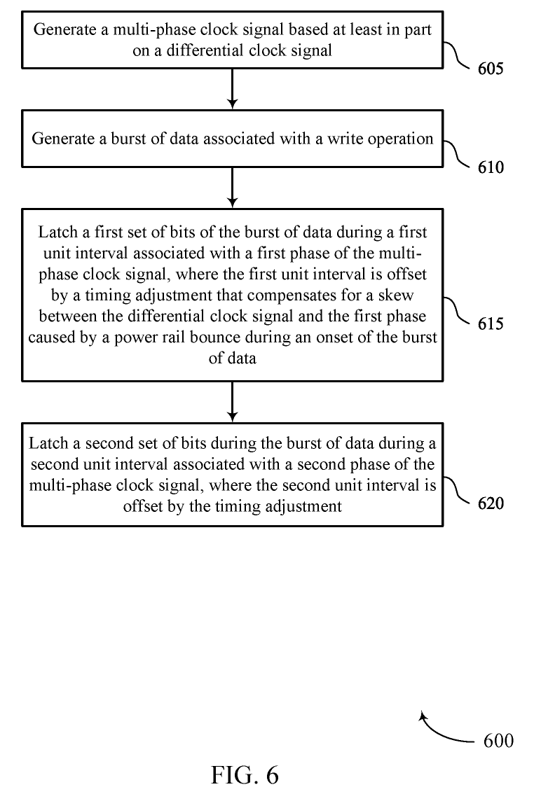

FIG. 6 shows a flowchart illustrating a method 600 that supports adjustment to multi-phase clock to reduce skew variation caused by power rail bounce at an onset of a burst of data in accordance with examples as disclosed herein. The operations of method 600 may be implemented by an apparatus or its components as described herein. For example, the operations of method 600 may be performed by a memory system as described with reference to FIGS. 1 through 5. In some examples, a memory system may execute a set of instructions to control the functional elements of the device to perform the described functions. Additionally, or alternatively, the memory system may perform aspects of the described functions using special-purpose hardware.

At 605, the method may include generating a multi-phase clock signal based at least in part on a differential clock signal. In some examples, aspects of the operations of 605 may be performed by a clock generating component 510 as described with reference to FIG. 5.

At 610, the method may include generating a burst of data associated with a write operation. In some examples, aspects of the operations of 610 may be performed by a writing component 515 as described with reference to FIG. 5.

At 615, the method may include latching a first set of bits of the burst of data during a first unit interval associated with a first phase of the multi-phase clock signal, where the first unit interval is offset by a timing adjustment that compensates for a skew between the differential clock signal and the first phase caused by a power rail bounce during an onset of the burst of data. In some examples, aspects of the operations of 615 may be performed by a latching component 520 as described with reference to FIG. 5.

At 620, the method may include latching a second set of bits during the burst of data during a second unit interval associated with a second phase of the multi-phase clock signal, where the second unit interval is offset by the timing adjustment. In some examples, aspects of the operations of 620 may be performed by a latching component 520 as described with reference to FIG. 5.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for generating a multi-phase clock signal based at least in part on a differential clock signal; generating a burst of data associated with a write operation; latching a first set of bits of the burst of data during a first unit interval associated with a first phase of the multi-phase clock signal, where the first unit interval is offset by a timing adjustment that compensates for a skew between the differential clock signal and the first phase caused by a power rail bounce during an onset of the burst of data; and latching a second set of bits during the burst of data during a second unit interval associated with a second phase of the multi-phase clock signal, where the second unit interval is offset by the timing adjustment.

Aspect 2: The method, apparatus, or non-transitory computer-readable medium of aspect 1, further including operations, features, circuitry, logic, means, or instructions, or any combination thereof for latching a third set of bits of the burst of data using a third unit interval associated with a third phase of the multi-phase clock signal and where the third unit interval is offset by a second timing adjustment that compensates for a second skew between the differential clock signal and the third phase caused by the power rail bounce during the onset of the burst of data.

Aspect 3: The method, apparatus, or non-transitory computer-readable medium of aspect 2, further including operations, features, circuitry, logic, means, or instructions, or any combination thereof for latching a fourth set of bits of the burst of data using a fourth unit interval associated with a fourth phase of the multi-phase clock signal, where the fourth unit interval is offset by the second timing adjustment.

Aspect 4: The method, apparatus, or non-transitory computer-readable medium of any of aspects 1 through 3, where a data channel over which the burst of data is conveyed is in an idle state before the burst of data begins.

Aspect 5: The method, apparatus, or non-transitory computer-readable medium of any of aspects 1 through 4, further including operations, features, circuitry, logic, means, or instructions, or any combination thereof for determining whether a data channel over which the burst of data is conveyed is an idle state before the burst of the data begins and modifying the first phase of the multi-phase clock signal with the timing adjustment based at least in part on determining that the data channel was idle, where latching the first set of bits is based at least in part on modifying the first phase.

Aspect 6: The method, apparatus, or non-transitory computer-readable medium of aspect 5, further including operations, features, circuitry, logic, means, or instructions, or any combination thereof for generating a signal indicating that the data channel was in the idle state based at least in part on the determining, where modifying the first phase is based at least in part on generating the signal.

Aspect 7: The method, apparatus, or non-transitory computer-readable medium of any of aspects 5 through 6, further including operations, features, circuitry, logic, means, or instructions, or any combination thereof for retrieving a first value of the timing adjustment from a register and modifying the first value of the timing adjustment to a second value, where latching the first set of bits is based at least in part on the second value of the timing adjustment.

Aspect 8: The method, apparatus, or non-transitory computer-readable medium of aspect 7, where modifying the first value to the second value further includes operations, features, circuitry, logic, means, or instructions, or any combination thereof for adding a third value to the first value to generate the second value.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 9: An apparatus, including: first circuitry configured to: generate a multi-phase clock signal based at least in part on a differential clock signal; detect a leading phase of the multi-phase clock signal at an onset of a burst of data associated with a write operation; and generate pulse signaling that is indicative of the leading phase; and second circuitry configured to: receive the pulse signaling from the first circuitry; determine, using the pulse signaling, a timing adjustment that compensates for an increase in a skew between the leading phase and the differential clock signal caused by a power rail bounce at the onset of the burst of data; and provide the timing adjustment to the first circuitry to shift a unit interval of the leading phase to improve a centering of an edge of the unit interval with a data eye used to latch data at the onset of the burst of data.

Aspect 10: The apparatus of aspect 9, where the first circuitry includes: duty cycle timing adjustment circuitry configured to receive the timing adjustment from the second circuitry and shift the unit interval of the leading phase based on the timing adjustment.

Aspect 11: The apparatus of any of aspects 9 through 10, where the first circuitry includes a block of logic circuitry, the block of logic circuitry including: phase detecting circuit elements; and pulse signal generating circuit elements.

Aspect 12: The apparatus of aspect 11, where the phase detecting circuit elements is configured to: detect that a zero-degree reference phase of the multi-phase clock signal is the leading phase, or detect that a 180-degree phase of the multi-phase clock signal is the leading phase.

Aspect 13: The apparatus of any of aspects 11 through 12, where the phase detecting circuit elements is configured to detect the leading phase based on a write preamble setting.

Aspect 14: The apparatus of aspect 13, where the pulse signal generating circuit elements is configured to: generate, for a first two sets of bits written at the onset of the burst of data, pulse signaling that includes toggling a first flag output and clearing a second flag output.

Aspect 15: The apparatus of any of aspects 13 through 14, where the pulse signal generating circuit elements is configured to: generate, for a first three sets of bits written at the onset of the burst of data, pulse signaling that includes toggling a first flag output and toggling a second flag output.

Aspect 16: The apparatus of any of aspects 13 through 15, where the pulse signal generating circuit elements is configured to: generate, for a first four sets of bits written at the onset of the burst of data, pulse signaling that includes enabling a first flag output and a second flag output.

Aspect 17: The apparatus of any of aspects 11 through 16, where the block of logic circuitry further includes data channel monitoring circuitry configured to determine whether a data channel over which the burst of data is conveyed is an idle state before the burst of the data begins.

Aspect 18: The apparatus of any of aspects 9 through 17, where the second circuitry includes a block of logic circuitry, the block of logic circuitry including: first adder circuitry; and second adder circuitry.

Aspect 19: The apparatus of aspect 18, where the first adder circuitry is configured to: retrieve, from a register, test bits representing a first value of a timing adjustment to a zero-degree phase of the multi-phase clock signal and to a 90-degree phase of the multi-phase clock signal; receive, from the first circuitry, the pulse signaling; and modify, based at least in part on the test bits and the pulse signaling, the timing adjustment to a second value; and output, to the first circuitry, the timing adjustment, where the timing adjustment is modified to the second value.

Aspect 20: The apparatus of any of aspects 18 through 19, where the second adder circuitry is configured to: retrieve, from a register, test bits representing a first value of a timing adjustment to a 180-degree phase of the multi-phase clock signal and to a 270-degree phase of the multi-phase clock signal; receive, from the first circuitry, the pulse signaling; and modify, based at least in part on the test bits and the pulse signaling, a timing adjustment to a second value; and outputting, to the first circuitry, the timing adjustment, where the timing adjustment is modified to the second value.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, instructions (e.g., code, software, firmware, logic) executed by a processing system (e.g., one or more processors, one or more controllers, control circuitry, processing circuitry, logic circuitry), or any combination thereof that is configured to cause a respective apparatus, device, or system to perform the described functions. If implemented as instructions executed by a processing system, the functions may be stored on or transmitted over as one or more instructions on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof, that are configured to cause the performance of the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
first circuitry configured to:
generate a multi-phase clock signal based at least in part on a differential clock signal;
detect a leading phase of the multi-phase clock signal at an onset of a burst of data associated with a write operation; and
generate pulse signaling that is indicative of the leading phase; and
second circuitry configured to:
receive the pulse signaling from the first circuitry;
determine, using the pulse signaling, a timing adjustment that compensates for an increase in a skew between the leading phase and the differential clock signal caused by a power rail bounce at the onset of the burst of data; and
provide the timing adjustment to the first circuitry to shift a unit interval of the leading phase to improve a centering of an edge of the unit interval with a data eye used to latch data at the onset of the burst of data.

2. The apparatus of claim 1, wherein the first circuitry comprises:
duty cycle timing adjustment circuitry configured to receive the timing adjustment from the second circuitry and shift the unit interval of the leading phase based on the timing adjustment.

3. The apparatus of claim 1, wherein the first circuitry includes a block of logic circuitry, the block of logic circuitry comprising:
phase detecting circuit elements; and
pulse signal generating circuit elements.

4. The apparatus of claim 3, wherein the phase detecting circuit elements is configured to:
detect that a zero-degree reference phase of the multi-phase clock signal is the leading phase, or
detect that a 180-degree phase of the multi-phase clock signal is the leading phase.

5. The apparatus of claim 3, wherein the phase detecting circuit elements is configured to detect the leading phase based on a write preamble setting.

6. The apparatus of claim 5, wherein the pulse signal generating circuit elements is configured to:
generate, for a first two sets of bits written at the onset of the burst of data, pulse signaling that includes toggling a first flag output and clearing a second flag output.

7. The apparatus of claim 5, wherein the pulse signal generating circuit elements is configured to:
generate, for a first three sets of bits written at the onset of the burst of data, pulse signaling that includes clearing a first flag output and toggling a second flag output.

8. The apparatus of claim 5, wherein the pulse signal generating circuit elements is configured to:
generate, for a first four sets of bits written at the onset of the burst of data, pulse signaling that includes enabling a first flag output and a second flag output.

9. The apparatus of claim 3, wherein the block of logic circuitry further comprises data channel monitoring circuitry configured to determine whether a data channel over which the burst of data is conveyed is an idle state before the burst of the data begins.

10. The apparatus of claim 1, wherein the second circuitry includes a block of logic circuitry, the block of logic circuitry comprising:
first adder circuitry; and
second adder circuitry.

11. The apparatus of claim 10, wherein the first adder circuitry is configured to:
retrieve, from a register, test bits representing a first value of a timing adjustment to a zero-degree phase of the multi-phase clock signal and to a 90-degree phase of the multi-phase clock signal;
receive, from the first circuitry, the pulse signaling;
modify, based at least in part on the test bits and the pulse signaling, the timing adjustment to a second value; and
output, to the first circuitry, the timing adjustment, wherein the timing adjustment is modified to the second value.

12. The apparatus of claim 10, wherein the second adder circuitry is configured to:
retrieve, from a register, test bits representing a first value of a timing adjustment to a 180-degree phase of the multi-phase clock signal and to a 270-degree phase of the multi-phase clock signal;
receive, from the first circuitry, the pulse signaling;
modify, based at least in part on the test bits and the pulse signaling, a timing adjustment to a second value; and
outputting, to the first circuitry, the timing adjustment, wherein the timing adjustment is modified to the second value.

13. A method at a memory system, comprising:
generating a multi-phase clock signal based at least in part on a differential clock signal;
generating a burst of data associated with a write operation;
latching a first set of bits of the burst of data during a first unit interval associated with a first phase of the multi-phase clock signal, wherein the first unit interval is offset by a timing adjustment that compensates for a skew between the differential clock signal and the first phase caused by a power rail bounce during an onset of the burst of data; and
latching a second set of bits during the burst of data during a second unit interval associated with a second phase of the multi-phase clock signal, wherein the second unit interval is offset by the timing adjustment.

14. The method of claim 13, further comprising:
latching a third set of bits of the burst of data using a third unit interval associated with a third phase of the multi-phase clock signal,
wherein the third unit interval is offset by a second timing adjustment that compensates for a second skew between the differential clock signal and the third phase caused by the power rail bounce during the onset of the burst of data.

15. The method of claim 14, further comprising:
latching a fourth set of bits of the burst of data using a fourth unit interval associated with a fourth phase of the multi-phase clock signal, wherein the fourth unit interval is offset by the second timing adjustment.

16. The method of claim 13, wherein a data channel over which the burst of data is conveyed is in an idle state before the burst of data begins.

17. The method of claim 13, further comprising:
determining whether a data channel over which the burst of data is conveyed is an idle state before the burst of the data begins; and
modifying the first phase of the multi-phase clock signal with the timing adjustment based at least in part on determining that the data channel was idle, wherein latching the first set of bits is based at least in part on modifying the first phase.

18. The method of claim 17, further comprising:
generating a signal indicating that the data channel was in the idle state based at least in part on the determining, wherein modifying the first phase is based at least in part on generating the signal.

19. The method of claim 17, further comprising:
retrieving a first value of the timing adjustment from a register; and
modifying the first value of the timing adjustment to a second value, wherein latching the first set of bits is based at least in part on the second value of the timing adjustment.

20. The method of claim 19, wherein modifying the first value to the second value further comprises:
adding a third value to the first value to generate the second value.
